(19) United States
(12) Patent Application Publication
(10) Pub. No.: US 2023/0400517 A1
(43) Pub. Date: Dec. 14, 2023

(54) APPARATUS AND METHOD FOR RESONANT CIRCUIT DEVICE FOR MEASURING BATTERY LIFE

(71) Applicant: Gary Viviani, Lyle, WA (US)

(72) Inventor: Gary Viviani, Lyle, WA (US)

(21) Appl. No.: 17/840,199

(22) Filed: Jun. 14, 2022

(51) Int. Cl. G01R 31/367; G01R 13/02; G01R 31/3842

(52) U.S. Cl. CPC G01R 31/367; G01R 13/02; G01R 31/3842

(57) ABSTRACT

A system and method for battery testing is provided. A calibrated oscillator outputs an oscillating test signal with a known function. A signal response of the battery under test is detected while the calibrated oscillator outputs the oscillating test signal. A response test pattern for the battery under test is determined using the analyzed signal response information. The response test pattern is compared with a family of base response test patterns of a reference battery, wherein each one of the base response test patterns uniquely corresponds to one of a plurality of known battery conditions. A best match base response test pattern is identified from one of the family of base response test patterns that corresponds to the response test pattern for the battery under test. A battery condition for the battery under test is determined based on the known battery condition of the best match base response test pattern.

### BACKGROUND OF THE INVENTION

Electrical energy storage devices are in widespread use in the form of batteries, fuel cells, as well as other forms of devices. Determining the health and general useful life of such devices is both commonplace and important for production as well as end-use applications.

Existing methods for measuring the expected life of a battery are focused on an approach which attempts to make a direct measurement of the impedance of the battery. The variations in the battery impedance are known to be a representation of expected battery life. Such methods are well known.

One of the noteworthy limitations of existing impedance-based methods is that they are slow to determine the impedance of the battery. This limits the applicability of such methods. Time to measure the impedance of the battery varies with the particular approach applied, but the fastest approach to spectrally determining the impedance may be as long as 10 seconds.

This long duration is not acceptable for many applications such as a quick health check in a production environment. Other situations also require much faster measurements in order to be practical.

To emphasize what is lacking in the state of the art, it is worth noting that existing approaches to battery life determination rely on scientific grade instrumentation. This is very costly and complex. Additionally, the time to make a suitable measurement is orders of magnitude longer than what is described in this application. Therefore, there is a great need to reduce the cost, complexity and time to derive a measurement for the state of a battery.

By reducing the cost, complexity and time to derive the state of a battery, many new applications and capabilities result. For example, it is possible to embed a simple circuit in the battery itself. It is possible to make battery life determination a routine and even continuously monitored measurement associated with production, storage and end-use applications of battery technology.

Additionally, it is worth noting that the typical end-use battery consumer has little knowledge about the actual state of a battery. For the typical end use customer, the only measurement available is when the device requiring battery power fails to function correctly. The end-user has only the option to replace the battery and determine if that solves the problem. No specific measurement is generally available in many end-use applications. Additionally, batteries that have been in storage for extended periods also provide no specific indication of state. Again, the alternative is to insert the battery into the intended device which requires battery power and determine if it functions as desired, or not. Finally, in the manufacture process for batteries, it is too costly and time consuming to measure the state of all batteries. Hence, quality control is not as good as it could be if the state of every battery in the production flow was measured, as is possible with the device described in this patent application.

Accordingly, in the arts of battery testing, there is a need in the arts for improved methods, apparatus, and systems assessing condition of a battery.

### SUMMARY OF THE INVENTION

Real-time battery assessment of life expectancy is accomplished by determining a characteristic resonance due to the characteristic impedance of the battery under test. The well-known fact that the impedance of a battery varies monotonically is exploited by measuring the resultant phase plane oscillation associated with the parallel impedance of the reference oscillator combined with the impedance of the battery under test. The nature of the resultant oscillation provides a virtually instantaneous indication of the state of the battery where the time required is inversely proportional the frequency of the oscillator. This approach represents a significant breakthrough in both the time necessary to determine the state of a battery, as well as greatly simplifying the complexity and cost as compared to existing approaches. This approach makes it feasible to include an indication of the state of the battery as an integral component in all batteries. This is especially true for rechargeable batteries

### BRIEF DESCRIPTION OF THE DRAWINGS

The components in the drawings are not necessarily to scale relative to each other. Like

reference numerals designate corresponding parts throughout the several views.

FIG. 1. Is a block diagram of a battery test system.

FIG. 2 is a conceptual circuit diagram of a calibrated oscillator residing in the battery test system.

FIG. 3 is an illustration of the nonlinear characteristic, F(x), of FIG. 2.

FIG. 4 is an illustration of a characteristic phase plane oscillation of the calibrated oscillator.

FIG. 5 is an illustration of a circuit diagram of an example calibrated oscillator.

FIG. 6 is an illustration of a characteristic phase plane oscillation of the calibrated oscillator of FIG. 5.

FIG. 7 is an illustration of a circuit diagram of an example calibrated oscillator.

FIG. 8 is an illustration of a characteristic phase plane oscillation of the calibrated oscillator of FIG. 7.

FIG. 9 is an illustration of the variations of the nonlinear characteristic, F(x), caused by a plurality of different test conditions.

FIG. 10 is an illustration of an example plurality of base response test patterns (phase plane oscillations).

FIG. 11 is an illustration of an example response test pattern of a battery under test mapped onto a plurality of base response test patterns from a reference battery.

### DETAILED DESCRIPTION

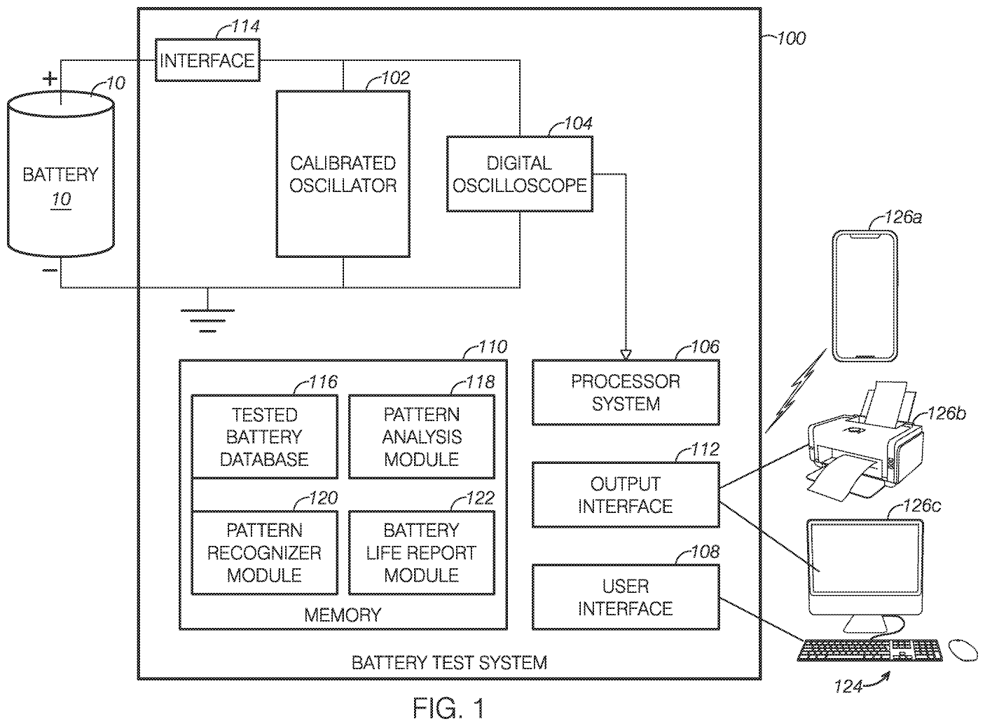

FIG. 1. is a block diagram of a battery test system 100. The battery test system 100 is configured to electrically couple to a battery 10 that is under test. An oscillating test signal (voltage and/or current) generated by the calibrated oscillator 102 is output and is received by the battery 10. The digital oscilloscope 104 detects the signal response of the parallel combination of the battery 10 and the calibrated oscillator 102 while the calibrated oscillator 102 is outputting the oscillating test signal. The digital oscilloscope 104 outputs signal response information corresponding to the detected signal response to the processor system 106. The processor system 106, after receiving user input at the user interface 108 that identifies the battery 10, initiates a test process wherein the calibrated oscillator 102 is activated (turned on).

Previously acquired test data pertaining to a reference battery that has been previously tested is retrieved from memory 110. Since the reference battery corresponds to the same type as the battery 10 under test, the battery test data acquired by the digital oscilloscope 104 is compared with the retrieved previously acquired test data. A comparison between the previously acquired test data and the acquired battery test data is used to determine a battery condition of the battery 10 that is under test. For example, the determined battery condition may correspond to a remaining useful battery life of the battery 10. A report may be then generated and output to a reporting device 126 via the output interface 112.

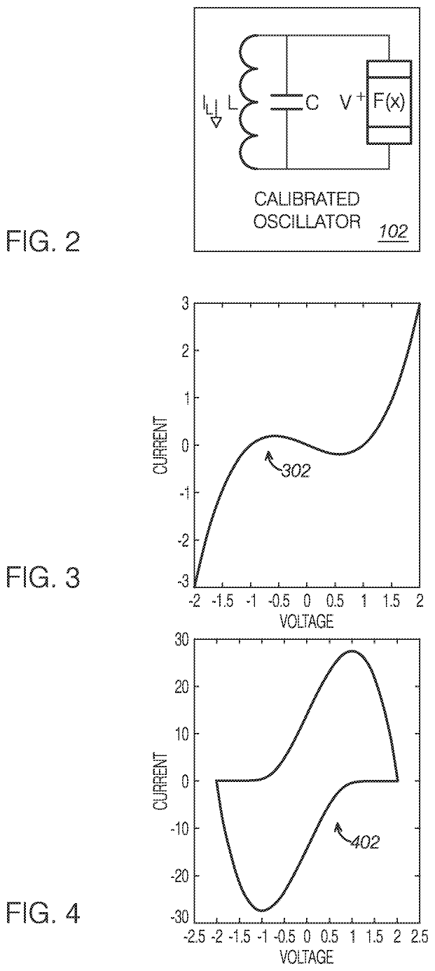

FIG. 2 is a conceptual circuit diagram of a calibrated oscillator 102 residing in the battery test system 100 that results from pairing an L (inductor) and C (capacitor) with a specially designed nonlinearity F(x). In this configuration, x corresponds to a voltage for the indicated circuit. However, x could represent a variety of entities that are equivalent to this circuit.

The disclosed systems and methods for a battery test system 100 will become better understood through review of the following detailed description in conjunction with the figures. The detailed description and figures provide examples of the various inventions described herein. Those skilled in the art will understand that the disclosed examples may be varied, modified, and altered without departing from the scope of the inventions described herein. Many variations are contemplated for different applications and design considerations, however, for the sake of brevity, each and every contemplated variation is not individually described in the following detailed description.

Throughout the following detailed description, a variety of examples for systems and methods for a battery test system 100 are provided. Related features in the examples may be identical, similar, or dissimilar in different examples. For the sake of brevity, related features will not be redundantly explained in each example. Instead, the use of related feature names will cue the reader that the feature with a related feature name may be similar to the related feature in an example explained previously. Features specific to a given example will be described in that particular example. The reader should understand that a given feature need not be the same or similar to the specific portrayal of a related feature in any given figure or example.

The following definitions apply herein, unless otherwise indicated.

“Substantially” means to be more-or-less conforming to the particular dimension, range, shape, concept, or other aspect modified by the term, such that a feature or component need not conform exactly. For example, a “substantially cylindrical” object means that the object resembles a cylinder, but may have one or more deviations from a true cylinder.

“Comprising,” “including,” and “having” (and conjugations thereof) are used interchangeably to mean including but not necessarily limited to, and are open-ended terms not intended to exclude additional elements or method steps not expressly recited.

Terms such as “first”, “second”, and “third” are used to distinguish or identify various members of a group, or the like, and are not intended to denote a serial, chronological, or numerical limitation.

“Coupled” means connected, either permanently or releasably, whether directly or indirectly through intervening components. “Secured to” means directly connected without intervening components.

“Communicatively coupled” means that an electronic device exchanges information with another electronic device, either wirelessly or with a wire based connector, whether directly or indirectly through a communication network. “Controllably coupled” means that an electronic device controls operation of another electronic device. “Electrically coupled” means that two electrical components are electrically coupled together in parallel and/or in series, as is known in the electrical arts.

Returning to FIG. 1, a non-limiting exemplary battery test system 100 comprises a calibrated oscillator 102, a digital oscilloscope 104, a processor system 106, a memory 110, an output interface 112, and a battery interface 114. The memory 110 comprises portions for storing a tested battery database 116, a pattern analysis module 118, a pattern recognizer module 120, and a battery life report module 122. In some embodiments, the pattern analysis module 118, the pattern recognizer module 120, and/or the battery life report module 122 may be integrated together, and/or may be integrated with other logic. In other embodiments, some or all of these memory and other data manipulation functions may be provided by using a remote server or other electronic devices suitably connected via the Internet or otherwise to a client device. Other battery test systems 100 may include some, or may omit some, of the above-described media processing components. Further, additional components not described herein may be included in alternative embodiments.

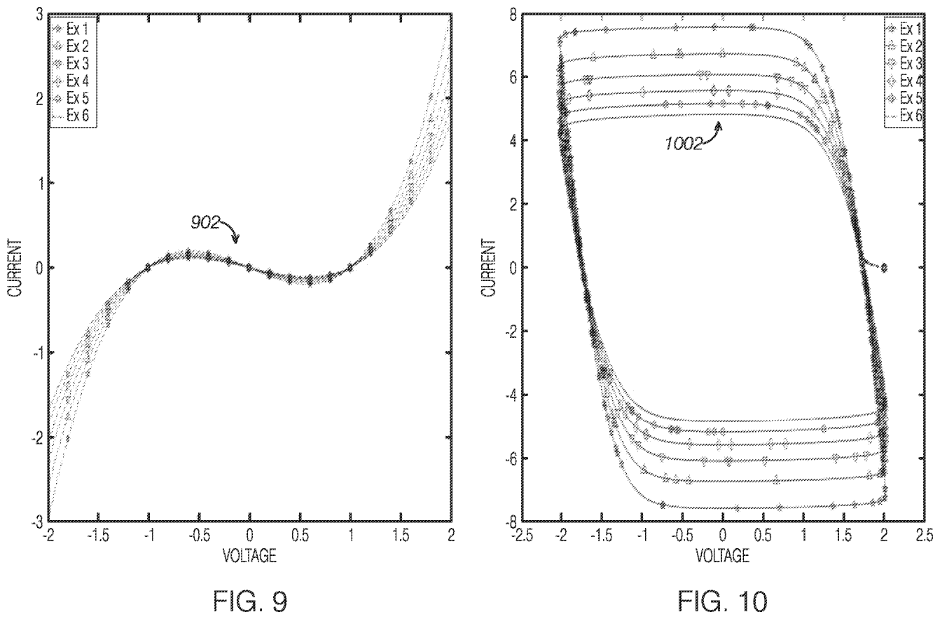

In a preferred embodiment, the tested battery database 116 has stored base response test pattern data. The base response test pattern data acquired for the previously tested different types of reference batteries is preferably stored as a plurality of base response F(x) nonlinearities 902 (see FIG. 9) or family of phase plane oscillations 1002 (see FIG. 10), both interchangeably referred to herein as base response test patterns. Each one of the base response test patterns in the family of base response test patterns corresponds to battery test results for that particular type of reference battery when at a particular known battery condition. Accordingly, for a particular type of reference battery, a family of base response test patterns is acquired, where each one of the base response test patterns is associated with a different battery condition. The families of base response test patterns may be saved in other forms and/or formats. All such embodiments are intended to be included within the scope of this disclosure and to be protected by the accompanying claims

In a preferred embodiment, the family of base response test patterns for many different types of reference batteries is stored in the tested battery database 116. Accordingly, the battery test system 100 may be used to test any battery 10 so long as there is one family of base response test patterns for that same type of battery 10.

In some embodiments, such as when the battery 10 is in a particular type of device, then the family of base response test patterns for that particular type of battery is stored in the tested battery database 116. For example, but not limited to, the battery 10 may reside in an electric vehicle or hybrid vehicle. Here, the battery test system 100 may be integrated into the electronics system of the vehicle. The user of the vehicle can conduct a battery test of the vehicle's battery 10 in real time or near real time.

Preferably, the family of base response test pattern data from the previously tested reference batteries was acquired by the battery test system 100. However, this approach may not be practical since once a battery 10 has degraded below its useful battery life, that battery 10 must be replaced.

Alternatively, the family of base response test patterns may be acquired using a different battery test system 100 so long as the calibrated oscillators 102 are like calibrated. The family of base response test patterns for a plurality of different types of reference batteries may be remotely stored. The family of base response test pattern data for a particular type of reference battery of interest can then be downloaded into the tested battery database 116. Here, the reference battery of interest is the same type of as the batter 10 that is under test.

Also, for each previously tested types of reference batteries in the tested battery database 116, corresponding tested battery identification information is associated with each particular family of previously acquired base response test patterns. This associated battery identification and family of base response test pattern information is stored in the tested battery database 116.

In practice, the user electrically connects the positive terminal of the battery 10 to the interface 114 so that the digital oscilloscope 104 and the battery 10 are then electrically coupled together in parallel. The calibrated oscillator 102 is then actuated to generate the test signal that is received by the battery 10. The response of the battery 10 to the test signal is then detected by the digital oscilloscope 104. The digital oscilloscope 104 outputs the acquired battery test response pattern data to the processor system 106. The processor system 106, executing the pattern analysis module 118, determines a response test pattern for the battery 10.

Prior to the battery test, or at least prior to determination of the battery condition, the user inputs information that identifies the battery 10. The user input information may be input via the user interface 108 using a suitable user input device 125 (such as a keyboard, a mouse, a touch sensitive display, etc.). The battery identification information of the battery 10 may include a battery manufacturer name, a type of battery type, battery name, a battery model number, a battery serial number, or the like.

The processor system 106, executing the tested battery database 116, compares the received battery identification information with corresponding identification information for a plurality of different types of reference batteries stored in the tested battery database 116. At some juncture during this comparison process, the processor system 106 identifies one of the types of previously tested reference batteries that matches the identification information of the battery 10 that is being tested. When a match is identified between the battery identification information of the battery 10 under test and the reference battery, the processor system 106 retrieves the previously acquired base test data for that matching previously tested battery.

The processor system 106, executing the pattern recognizer module 120, then compares the determined response test pattern for the battery 10 with family of base response test patterns for the corresponding reference battery. When a match between the determined response test pattern for the battery 10 and one of the family of base response test patterns is identified, battery state information associated with the matching base response test pattern is retrieved from the tested battery database 116. For example, but not limited to, the battery state information for the previously acquired response test pattern of the reference battery may indicate a remaining life of seventy-five percent (75%). Accordingly, the remaining life of the battery 10 under test can be estimated to be 75% by the processor system 106.

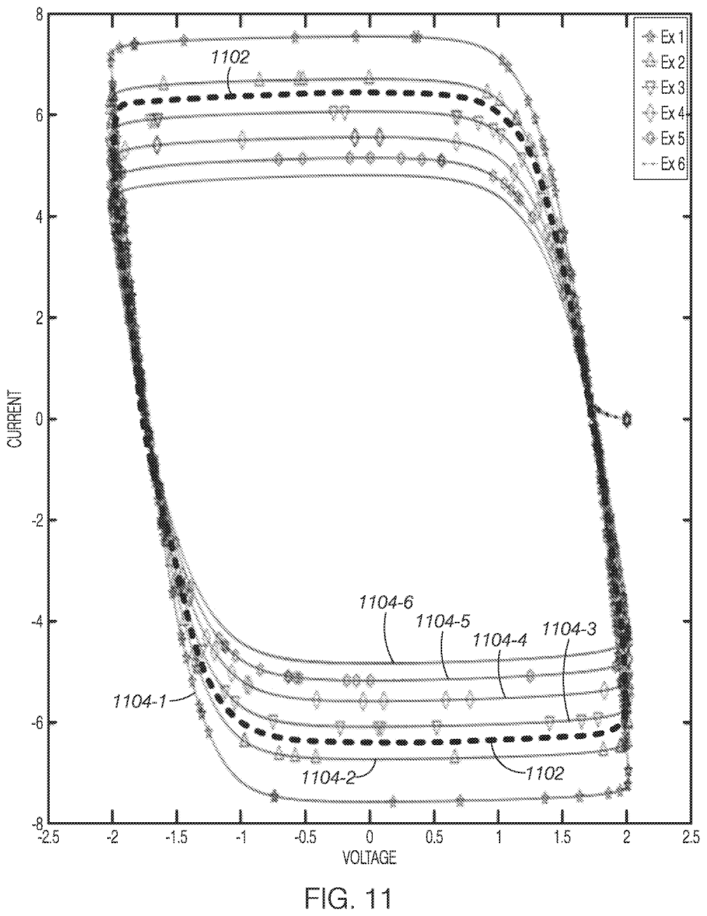

FIG. 11 is an illustration of an example response test pattern 1102 of a battery 10 under test mapped onto a family of base response test patterns 1104-1 (EX 1) to 1104-6 (EX 6) for a like-reference battery. Here, the response test pattern 1102 lies between the base response test pattern 1104-2 (EX 2) and 1104-3 (EX 3). The processor system 106 may determine that, for example, the response test pattern 1102 is closest to the base response test pattern 1104-2. Then, the battery condition associated with the base response test pattern 1104-2 can be retrieved and reported out to the user.

Some embodiments may be configured to use a suitable interpolation algorithm to compute the battery condition for the response test pattern determined for the battery using the family of base response test patterns for that type of battery. In the illustrative example of FIG. 11, the processor system 106 may retrieve the battery condition associated with the base response test pattern 1104-2 and for the base response test pattern 1104-3. Since the response test pattern 1102 lies between the base response test pattern 1104-2 and the base response test pattern 1104-3, an interpolated battery condition value may be computed using the corresponding known battery conditions for the base response test pattern 1104-2 and for the base response test pattern 1104-3.

Once the battery condition for the battery 10 has been determined, the processor system 106, executing the battery life report module 122, may then generate a report indicating the determined battery state information indicating the battery condition of the tested battery 10. The generated report may be output, via the output interface 112, to a reporting device 126. Non limiting example of a reporting device 126 may be a smart phone 126a, a printer 126b, and/or a display screen 126c. Any suitable reporting device 126 may be used by the various embodiments. In some applications, the reporting device 126 may also be used as a user input device 124, such as the smart phone 126a. As is well-known in the electrical arts, any electronic oscillator is characterized by an equation of the form of equation (1), which has an equivalent circuit described by FIG. 2.

\ddot{x}+μf(x)\dot{x}+x=0, (1)

μF(x)=∫₀^{x}μf(s)ds. (2)

The derivation of the above equations (1) and (2) is straightforward. By applying Kirchhoff s Current Law to the circuit of FIG. 2, the following equation (3) results.

$$\frac{{d}^{2} V}{d {t}^{2}} + \frac{L}{C} f ( V ) \frac{d V}{d t} + \frac{1}{L C} V = 0 \qquad ( 3 )$$

$$If \sqrt{\frac{1}{LC}} = 1 ,$$

which is imposed as a constraint to simplify the equation, then (1) results with

$$μ = \sqrt{\frac{L}{C}} .$$

Since, due to physical limitations

$$\sqrt{\frac{1}{LC}} = 1$$

is only mathematically valid, an actual circuit will have a scaling factor that can be ignored with respect to determining the shape of the phase plane characteristics. To avoid such scaling, the equivalent formulation of (3) can be used instead, at the expense of more complex visualizations of results. x is also substituted for V in order to highlight the generality of this result, which has both physical and mathematical significance. All the descriptions which follow could be formulated in terms of equations (1), or (3). In a non-limiting example embodiment, equation (1) is chosen because it is slightly simpler in form. This is a completely general result for any oscillator circuit. Also, an equivalent circuit, where x=a current, instead of a voltage, is also possible to derive. For this disclosure only the voltage-based embodiment is utilized, but it is evident than an alternative current-based embodiment, with equivalent dynamics is known to those skilled in the art.

Without exclusion to other embodiments, it can be assumed that x in equation (1) is a voltage and that would correspond to V in FIG. 2. The following definitions apply to FIG. 2:
x as defined by FIG. 2 and equations (1) and (2) is a voltage with units of volts.
   \dot{x}
      is defined as the time-based derivative of x, which can also be defined as

$$\frac{d x}{d t}$$

as is well-known in mathematics.
It has units of volts/sec.
\ddot{x} is defined as the second time-based derivative of x, which can also be defined as

$$\frac{{d}^{2} x}{d {t}^{2}}$$

as is well-known in mathematics. It has units of ^{volts}_{/sec}².
∫₀^{x}
   for equation (2) is the standard mathematical operation of integration.
s is a dummy variable to integration.
L as defined by the circuit of FIG. 2 is an inductor with an inductance that is measured in the standard units of henries.
C as defined by the circuit of FIG. 2 is a capacitor with a capacitance that is measured in the standard units of farads.
μ is defined by equations (1) and (2) and FIG. 2 corresponds to \sqrt{1/C}.
ω of equation (1) is proportional to the frequency of the oscillations associated with equation (1) and FIG. 2. It can be defined as ω²=1/LC. Therefore ω has units of

$$\frac{1}{sec} .$$

The term, “phase plane” is a precise mathematical term meant to describe a planar representation of two quantities such that dx/dt versus x is presented. For an electrical circuit, this is equivalent to the i (current) versus v (voltage) plane. As is seen, in FIG. 2, all the components share the same voltage, which is on the horizontal axis in a standard phase plane representation. In this disclosure, the current in the inductor, L, is utilized to characterize the phase plane dynamics of the circuit of FIG. 2. This current in the inductor is associated with the vertical axis of the phase plane. Alternative current choices, or else sums of currents, are possible. This would result in an alternative, but equivalent description of the dynamics of the system. Hence, the choices made are not binding and other equivalent choices exist. It is also worth noting that current can be measured in a variety of manners, however, one of the simplest is to measure the voltage across a small resister that is placed in series with the inductor, L, FIG. 2. Assuming the chosen resister has a sufficiently low resistance, it will not significantly modify the dynamics of the system. Standard means that are well-known to those skilled in the art are available to measure the voltage across the elements of FIG. 2. Hence, for the results of this disclosure it is considered to be a straightforward task to measure the current in the inductor, L, as well as the voltage across all the elements. With these two dynamical (time varying) measurements, the characteristics of the phase plane are precisely determined.
The main point of this disclosure is the fact that useful information about the state of a battery is derived from a phase-plane characterization of the dynamics of a battery in parallel with a suitable oscillator, equation (1). Preferably, all information must be representable as a closed curve in the phase plane. Hence, this disclosure is taking advantage of a not so well known mathematical fact to achieve a very practical and useful purpose, and that has not previously been described or exploited.

It is well-known that batteries have a characteristic impedance. One skilled in the art appreciates that impedances, in an electrical parallel combination, result in a so-called equivalent impedance. Assuming impedance is a complex number, which is usual, and that it is indicated by the nomenclature Z (as is usual), the equivalent impedance that is governed by two parallel impedances is determined by equation (4).

$$\frac{1}{{Z}_{e q u i v a l e n t}} = \frac{1}{{Z}_{1}} + \frac{1}{{Z}_{2}} \qquad ( 4 )$$

For this disclosure, without elimination of other equivalent considerations, Z₁ can be thought to represent the impedance of F(x), and Z₂ can be thought to represent the impedance of the battery under test. Z₂ is well-known to have the important characteristic that it varies in a monotonic fashion over the life of the battery. Hence, it is a well-performing indicator of battery life. Certain regular phases of Z₂ are known to have a 1-to-1 correspondence to battery life.

When the battery 10 is connected, the characteristic oscillation 302, 402 of the

calibrated oscillator 102 will achieve a 1-to-1 mapping of the characteristic impedance (response test pattern) of the battery 10, which is associated with the frequency of oscillation of the oscillator described by equation (1). This characteristic measurement can be thought of as converting from the impedance measurements to the phase plane measurements (see the characteristic oscillation 302 in FIG. 3, and the characteristic oscillation 402 in FIG. 4) for the chosen frequency of oscillation described by equation (1). These characteristic oscillations 302, 402 are interchangeably referred to herein as a response test pattern.

In order to maximize performance, it is prudent to choose an oscillator frequency of operation that corresponds to a section the battery impedance characteristics that experiences the greatest variation as a function of the age of the battery. Accordingly, there is typically greater variation in the impedance of the battery 10 at higher frequencies. The calibrated oscillator 102 is ideally suited to operate at the higher frequencies of interest. However, if appropriate, any frequency of interest can be accommodated. It is expected that the best frequency of operation will be a function of the nature of the battery under test. Without expert knowledge of the nature of the battery impedance characteristics, any oscillator frequency is likely to work satisfactorily.

It is also worthwhile to note that the oscillators under consideration are not pure sinusoidal oscillations, which would be characterized by a very “round” circle in the phase plane. Hence, non-sinusoidal oscillations, based on Fourier Analysis, can be thought of as being comprised of more than one sinusoid component. Therefore, the interaction with the impedance of the battery is actually distributed across more than one frequency, which only tends to improve the accuracy of the phase plane measurement, derived from the parallel combination of the oscillator impedance and that of the battery under test, which is the focus of this disclosure.

The phase plane oscillation of the calibrated oscillator 102, when placed in parallel with the battery 10 under test, will result in a monotonically varying oscillation (see FIGS. 3-4 and 9-10), according to the variation in impedance of the battery, and consistent with battery's life-state. It should be emphasized that FIGS. 3-4 and 9-10 are only representative in nature. The actual shapes of the associated curves can vary, but they will qualitatively achieve the same characterization.

The significant advantage of this approach is that the measurement that is derived from the shape and location of the closed curve in the phase plane of FIG. 9 and/or FIG. 10 will be a virtually instantaneous read-out of the life-state of the battery under test. Here, the actual time to achieve the measurement will be inversely proportional to the oscillation frequency, which is governed, and selectable, by the L and C of FIG. 2. The only requirement is that the L, and C are determined according to standard oscillator design methods.

Moreover, the circuitry for a suitable F(x) is relatively simple and requires only a DC source. This means that the entire apparatus, shown in FIG. 8, could become an integral (in situ) part of the battery itself and it could rely on the battery as it sole source of energy. Hence, the measurement could be insitu to the battery 10, and present in all batteries, assuming that a suitable means for measuring the resultant phase plane oscillation, or an equivalent, were additionally added in order to provide a sufficiently simple read-out. This is straightforward to accomplish in the form of a dedicated circuit. In some embodiments, such a dedicated circuit may be imbedded within the battery 10.

FIG. 2 provides an illustrative description of a calibrated oscillator 102, and is representative of a wide variety of oscillators assuming there is a suitable nonlinearity in the form of F(x) that is in parallel with an inductor, L, and capacitor, C. A suitable nonlinearities can be developed in a variety of manners. For this disclosure only a relatively simple nonlinearity is necessary, because the minimal number of oscillations necessary is singular. In particular, by creating a suitable F(x), that is still represented by the circuit of FIG. 2, it is possible for the additional oscillations to combine in a manner such that an even more precise and invariant oscillation is possible. For the purpose of battery measurements, a relatively simple nonlinearity is likely more than sufficient. However, if even greater precision is required, then the more complex formulations for F(x) are readily applied to the circuit of FIG. 2 to provide additional precision, should it be necessary. One skilled in the art appreciates that there exist a variety of methods to determine a suitable F(x). The approaches range from circuits that rely only on elemental transistors, to those that rely on operational amplifiers (OPAMPS). In this disclosure, an F(x) based on OPAMPS is presented because this configuration if very stable for a wide range of temperatures and therefore has desirable characteristics. Other equivalent embodiments are possible. All such variations are intended to be include within the scope of this disclosure and to be protected by the accompanying claims.

The calibrated oscillator 102 of FIG. 2 provides credibility to this disclosure. It is representative an embodiment that is well known to operate as described herein. All such variations are intended to be included within the scope of this disclosure and to be protected by the accompanying claims.

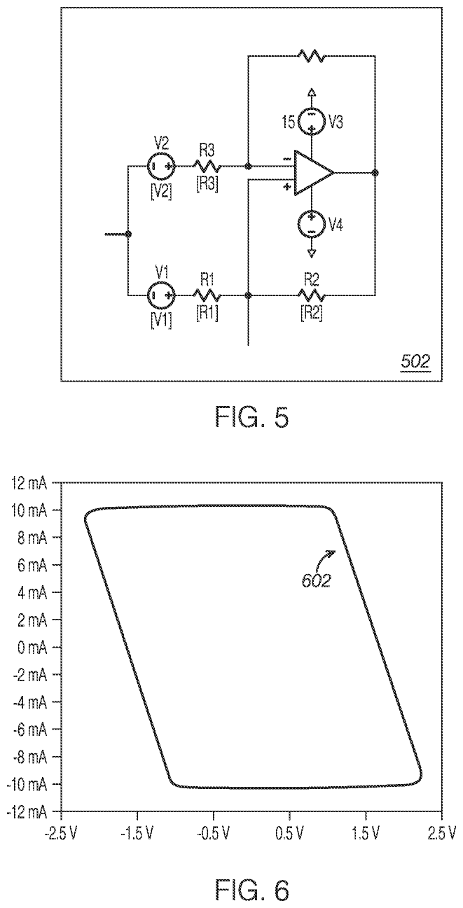

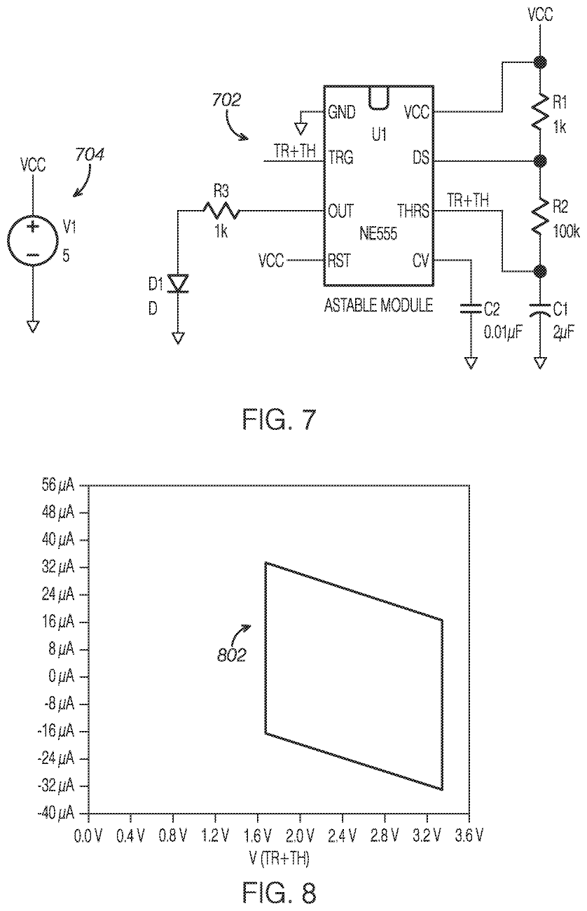

The calibrated oscillator 102 of FIG. 1 that has been electrically coupled to a battery 10 is the key element of this disclosure. It recognizes that if a battery 10 is connected in parallel with a suitable calibrated oscillator 102, such as the one described in FIG. 2 (or else one as described in FIG. 5 or 7), then the resultant oscillation will be different than the oscillation associated with calibrated oscillator 102 when not interacting with (disconnected from) the battery 10. Moreover, the resultant phase plane representation when the calibrated oscillator 102 and battery 10 are connected will provide a 1-to-1 mapping to the impedance characteristics associated with battery life. Traditionally, battery impedance measurements are well-known to characterize battery life. Since this one-to-one mapping is performed with the calibrated oscillator 102, the characterization in the phase-plane is essentially instantaneous, as it takes an epoch of time that is inversely proportional to the frequency of the calibrated oscillator 102. This is typically a time requirement that is less than a millisecond. By comparison, existing approaches for determining the impedance of a battery take a very long time. The fastest legacy approaches require on the order of 10 seconds. Hence, the subject of this disclosure, which relies on a calibrated oscillator 102 in parallel with a battery 10, is orders of magnitude faster.

FIG. 3 is description of a typical nonlinearity, F(x), for the calibrated oscillator 102. This is the same F(x) as described in FIG. 2.

FIG. 4 indicates what the resultant phase plane oscillation looks like when the phase plane is determined by the current in the inductor of FIG. 2 and the voltage across all the elements of the circuit of FIG. 2. Other choices of current measurement are possible, but any choice with result in a similar dynamical characterization. The choices shown are convenient for practical considerations associated with actual devices.

FIG. 5 provides an exemplary circuit 502 that create as suitable nonlinearity, F(x) using an operational amplifier (op amp). A typical nonlinearity, and hence the oscillator of FIG. 5 requires two sources to output a response test pattern 602 illustrated in FIG. 6. This is the case for the circuit 502. Hence the circuit 502 would not be suitable for an insitu battery device dependent upon the battery as a sole source of energy.

FIG. 7 indicates how it is possible to build an oscillator 702 when only a single DC source 704 is available. In this case, the oscillator circuit 702 relies on a standard off-the-shelf NE555 integrated circuit. The complexity inside this integrated circuit 702 is creating the equivalent of a second DC source. Hence, a suitable phase plane measurement represented by the response test pattern 802 of FIG. 8 is accomplished by measuring the current (test current information) and voltage (test voltage information) associated with C1. Other methods for developing a single source Calibrated Oscillator are possible, and they will lead to variations compared to the embodiment illustrated in FIG. 2. All such variations are intended to be included within the scope of this disclosure and to be protected by the accompanying claims.

FIG. 9 shows the effect of placing a reference battery in parallel with the circuit of FIG. 2. Here, a family of base response test patterns 902 includes test voltage information and test current information associated with the remaining battery life value of a reference battery. There is a one to one mapping associated the various phases of battery life. Assuming that there are 6 phases of battery life, that are characterized by 6 different impedance curves, then there will be 6 different resultant nonlinearities (previously acquired response test patterns for the reference battery) resulting from the configuration shown in FIG. 1 (the previously acquired test data of a previously tested reference battery that has been previously stored in the tested battery database 116).

These previously acquired response test patterns for the reference battery are illustrated in FIG. 9 as EX 1, EX 2, EX 3, EX 4, EX 5, and EX 6 (and are referred to as a family of base response test patterns). For each of these nonlinearities, there will be a slightly different phase plane characterization of the resultant oscillation, resulting in a unique base response test pattern. For example, the first phase plane curve of EX 1 corresponds to a first known battery condition for that reference battery. The second phase plane curve of EX 1 corresponds to a second known battery condition for that reference battery.

One skilled in the art appreciates that to generate the plurality of first phase plane curves for a reference battery, a plurality of reference batteries each at different battery conditions must be pre-tested to determine their respective battery condition. For example, when the first phase plane curves EX 1, EX 2, EX 3, EX 4, EX 5, and EX 6 are acquired, six reference batteries with different battery conditions are tested to determine their respective phase plane curve (family of base response test patterns). Since each of the tested reference batteries are identical, other than their battery condition, then an assumption can be made that if the battery 10 under test is of the same type as the tested plurality of like batteries, that the first phase plane curves of the reference batteries will correspond to the first phase plane curve (the response test pattern) of the battery 10 under test.

Accordingly, as described herein, the phase plane curve of the battery 10 may be compared to the phase plane curves of the plurality of pre-tested reference batteries. The assumption then is that the phase plane curve of the battery 10 under test that best matches one of the plurality of phase plane curves will correlate to the battery condition of the pre-tested like battery having the best-matched phase plane curve. In some embodiments, a suitable interpolation process between two closest phase plane curves may be made to more closely approximate the battery condition of the battery 10 under test.

FIG. 10 shows the different phase plane patterns 1002 that result for each of the EX 1, EX 2, EX 3, EX 4, EX 5, and EX 6 nonlinearities that correspond to the various phases of battery life in a previously tested reference battery (or like batteries). When a comparison is made of the response of the battery 10 under test, the is a near instantaneous indication of the phase of life of a particular battery 10 under test (measurement).

In the various embodiments, the processing system 106 may be any suitable processor or device. The processing system 106 may be a commercially available processor. Examples of commercially available processors include, but are not limited to, a Pentium microprocessor from Intel Corporation, Power PC microprocessor, SPARC processor, PA-RISC processor or 68000 series microprocessor. In other embodiments, the processing system 106 may be a mainframe type processor system. The processing system 106 may be a specially designed and fabricated processor, or may be part of a multi-purpose processing system, in accordance with embodiments of the battery test system 100.

It should be emphasized that the above-described embodiments of the battery test system 100 are merely possible examples of implementations of the invention. Many variations and modifications may be made to the above-described embodiments. All such modifications and variations are intended to be included herein within the scope of this disclosure and protected by the following claims.

Furthermore, the disclosure above encompasses multiple distinct inventions with independent utility. While each of these inventions has been disclosed in a particular form, the specific embodiments disclosed and illustrated above are not to be considered in a limiting sense as numerous variations are possible. The subject matter of the inventions includes all novel and non-obvious combinations and subcombinations of the various elements, features, functions and/or properties disclosed above and inherent to those skilled in the art pertaining to such inventions. Where the disclosure or subsequently filed claims recite “a” element, “a first” element, or any such equivalent term, the disclosure or claims should be understood to incorporate one or more such elements, neither requiring nor excluding two or more such elements.

Applicant(s) reserves the right to submit claims directed to combinations and subcombinations of the disclosed inventions that are believed to be novel and non-obvious. Inventions embodied in other combinations and subcombinations of features, functions, elements and/or properties may be claimed through amendment of those claims or presentation of new claims in the present application or in a related application. Such amended or new claims, whether they are directed to the same invention or a different invention and whether they are different, broader, narrower, or equal in scope to the original claims, are to be considered within the subject matter of the inventions described herein.

Therefore, having thus described the invention, at least the following is claimed:

1. A battery testing system, comprising:
a calibrated oscillator configured to be coupled in parallel with a battery under test,
wherein the calibrated oscillator outputs an oscillating test signal defined by a known function of the calibrated oscillator, and
wherein the oscillating test signal is received by the battery under test during a battery test;
a processor system;
a digital oscilloscope communicatively coupled to the processor system,
wherein the digital oscilloscope detects a signal response of the battery under test during the battery test while the calibrated oscillator outputs the oscillating test signal, and
wherein the digital oscilloscope outputs signal response information that is communicated to the processor system; and
a memory communicatively coupled to the processor system,
wherein the memory stores a tested battery database,
wherein the tested battery database includes a family of base response test patterns for a reference battery that is of the same type as the battery under test,
wherein each one of the family of base response test patterns uniquely corresponds to one of a plurality of known battery conditions, and
wherein the memory stores a pattern analysis module,
wherein the pattern analysis module, when executed by the processor system, is configured to analyze the signal response information that is output by the digital oscilloscope,
wherein the pattern analysis module determines a response test pattern for the battery under test based on the analyzed signal response information,
wherein memory stores a pattern recognizer module that, when executed by the processor system, compares the response test pattern for the battery under test with the family of base response test patterns, and
wherein the processor system identifies a best match base response test pattern from one of the family of base response test patterns that corresponds to the response test pattern for the battery under test, and
wherein the processor system determines a battery condition for the battery under test based on the known battery condition that is associated with the identified best match base response test pattern.

2. The battery test system of claim 1,
wherein the battery condition associated with each one of the family of base response test patterns uniquely corresponds to one of a plurality of remaining battery life values, and
wherein the processor system determines a remaining battery life value for the battery under test based on the remaining battery life value that is associated with the identified best match base response test pattern.

3. The battery test system of claim 1,
wherein each one of the family of base response test patterns includes test voltage information and test current information.

4. The battery test system of claim 3, further comprising
an output interface communicatively coupled to the processor system,
wherein the processor system generates a graphical response test pattern based on the test voltage information and test current information, and
wherein the graphical response test pattern is presented on a display communicatively coupled to the output interface.

5. The battery test system of claim 3, further comprising
an output interface communicatively coupled to the processor system,
wherein the memory comprises a battery life report module,
wherein the processor system, executing the battery report module, generates battery condition information corresponding to the determined battery condition of the battery under test, and
wherein the generated battery condition information is communicated to a user device to inform a user of the user device of the battery condition value.

6. The battery test system of claim 1,
wherein the processor system identifies the best match base response test pattern from one of the family of base response test patterns that is a best match to the response test pattern for the battery under test.

7. The battery test system of claim 1,
wherein the processor system identifies two best match base response test patterns from the family of base response test patterns;
wherein the response test pattern lies between the two best match base response test patterns; and
wherein the processor interpolates between the two best match base response test patterns to determine the battery condition of the battery under test.

8. The battery test system of claim 1,
wherein the family of base response test patterns for the reference battery is a first family of base response test patterns for a first reference battery,
wherein the tested battery database includes a plurality of families of base response test patterns for a plurality of different types of reference batteries, and
further comprising:
a user interface communicatively coupled to the processor system and communicatively coupled to a user input device,
wherein a user specifies a type of the battery under test,
wherein the processor system identifies one of the families of reference batteries that has a reference battery type that matches the specified type of battery under test, and
wherein the family of base response test patterns associated with the identified reference battery is used to determine the battery condition for the battery under test.

9. A method of testing batteries, comprising:
coupling a plurality of reference batteries to a battery test system,
wherein each of the plurality of reference batteries is of a same type,
wherein each of the plurality of reference batteries has a remaining life value that defines a known remaining battery life of the reference battery, and
wherein the known remaining battery life of each one of the plurality of reference batteries are different from each other; and
applying an oscillating test signal generated by a calibrated oscillator to each of the plurality of reference batteries;
wherein for testing each one of the plurality of reference batteries, the method comprises:
detecting a response signal of the reference battery using a digital oscilloscope;
outputting from the digital oscilloscope response signal information corresponding to the detected response signal;
determining a base response test pattern based on the signal response information that is output by the digital oscilloscope, and
storing the determined base response test pattern and the associated remaining battery life value into the tested battery database residing in a memory of the battery test system, and
wherein after each of the plurality of reference batteries has been tested, the stored plurality base response test patterns is a family of base response test patterns associated with the type of the plurality of reference batteries.

10. The method of claim 9,
wherein each of the plurality of test patterns include test voltage information and test current information associated with the remaining battery life value.

11. The method of claim 9, wherein the family of base response test patterns for the type of reference battery is one of a plurality of family of base response test patterns for different types of reference batteries, the method further comprising:
receiving a user input that specifies a type for a battery under test;
applying the oscillating test signal generated by the calibrated oscillator to the battery under test;
outputting from the digital oscilloscope response signal information corresponding to the detected response signal;
determining a response test pattern for the battery under test based on the signal response information that is output by the digital oscilloscope;
comparing the determined response test pattern for the battery under test with the family of base response test patterns for the reference battery that is of the same type as the battery under test;
identifying a best match base response test pattern from one of the family of base response test patterns that corresponds to the response test pattern for the battery under test; and
determining a battery condition for the battery under test based on the known battery condition that is associated with the identified best match base response test pattern.

12. The method of claim 11,
wherein the battery condition is a remaining battery life value for the battery under test.

13. The method of claim 11,
wherein each one of the family of base response test patterns includes test voltage information and test current information.

14. The method of claim 11,
wherein the best match base response test pattern identified from one of the family of base response test patterns is a best match to the response test pattern for the battery under test.
